(19) United States
(12) Patent Application Publication
(10) Pub. No.: US 2012/0074561 A1
(43) Pub. Date: Mar. 29, 2012

(54) BACKMETAL REPLACEMENT FOR USE IN THE PACKAGING OF INTEGRATED CIRCUITS

(75) Inventors: Nghia T. TU, San Jose, CA (US); Will K. WONG, Belmont, CA (US); Jamie A. BAYAN, Palo Alto, CA (US)

(73) Assignee: NATIONAL SEMICONDUCTOR CORPORATION, Santa Clara, CA (US)

(21) Appl. No.: 12/891,440

(22) Filed: Sep. 27, 2010

(51) Int. Cl. H01L 23/34; H01L 21/50

(52) U.S. Cl. 257/712; 438/111; 257/E23.08; 257/E21.499

(57) ABSTRACT

One aspect of the invention pertains to an arrangement for forming exposed die packages. The arrangement includes a semiconductor wafer having multiple integrated circuit dice whose back surfaces cooperate to form the back surface of the wafer. A thermally conductive adhesive layer is deposited on the back surface of the wafer. The metal foil is attached to the wafer with the adhesive layer. Methods of forming exposed die packages using the above arrangement are also described.

### FIELD OF THE INVENTION

Generally, the present invention relates to the packaging of integrated circuit dice. More specifically, the present invention relates to methods and arrangements for forming exposed die packages.

### BACKGROUND OF THE INVENTION

There are a wide variety of integrated circuit packages. One type of package is an exposed die package. An integrated circuit die is electrically connected to an electronic substrate. Portions of the die and the electronic substrate are encapsulated in a molding compound such that the back surface of the die is exposed on the exterior of the package. The exposure of the back surface of the die facilitates the dissipation of heat out of the package.

For various applications, it is useful to coat the exposed back surface of the die with metal. For example, solder, which is often used to couple an integrated circuit package with a printed circuit board, adheres well to metal but poorly to the silicon surface of a die. Backmetalling the die allows the package to be securely mounted on the printed circuit board. One way of backmetaling the die is to do so at the wafer-level. That is, a metal coating is first applied to the back surface of a semiconductor wafer, which is later singulated to form multiple integrated circuit dice.

Since metal does not easily adhere to the silicon wafer, specialized processes, such as sputtering or evaporation, are generally used to backmetal the wafer. A typical sputtering process involves positioning the wafer and a metal target material in a suitable chamber. Energetic particles are generated from plasma in the chamber and directed towards the target material. The particles erode and physically eject metal atoms from the target material. The high-energy atoms condense to form a metal film that is securely and directly bonded to the wafer.

While the above processes work well, there are continuing efforts to develop improved packaging techniques that provide cost effective approaches for meeting the needs of a variety of different packaging applications.

### SUMMARY OF THE INVENTION

In one aspect of the present invention, an arrangement for forming exposed die packages will be described. The arrangement includes a semiconductor wafer having multiple integrated circuit dice whose back surfaces cooperate to form the back surface of the wafer. A thermally conductive adhesive layer is deposited on the back surface of the wafer. A thin metal foil is attached to the wafer with the adhesive layer. In some embodiments, the adhesive layer includes metal particles and is both electrically and thermally conductive.

In another aspect of the present invention, a method for forming exposed die packages will be described. A thermally conductive adhesive layer is deposited onto a back surface of an integrated circuit wafer. A metallic foil is attached to the back surface of the wafer using the adhesive layer. In various embodiments, the wafer may be singulated to form multiple integrated circuit dice. In still other embodiments, one of the dice is electrically connected to a lead frame. Portions of the lead frame and the die are encapsulated in a molding material such that the thin foil on the back surface of the die remains exposed.

### BRIEF DESCRIPTION OF THE DRAWINGS

The invention and the advantages thereof, may best be understood by reference to the following description taken in conjunction with the accompanying drawings in which:

FIGS. 1A and 1B are diagrammatic top and side views of an arrangement for forming exposed die packages according to a particular embodiment of the present invention.

FIG. 2 is a flow diagram that illustrates a method for forming exposed die packages according to a particular embodiment of the present invention.

FIGS. 3A-3D are diagrammatic side views of various operations in the method of FIG. 2 according to a particular embodiment of the present invention.

FIG. 3E is a diagrammatic top view of a lead frame strip according to a particular embodiment of the present invention.

FIGS. 3F-3G are enlarged views of various portions of the lead frame strip illustrated in FIG. 3D according to a particular embodiment of the present invention.

FIG. 3H-3I are diagrammatic side views of various operations in the method of FIG. 2 according to a particular embodiment of the present invention.

FIGS. 4A-4C are diagrammatic side views of different types of integrated circuit packages according to various embodiments of the present invention

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of integrated circuits. More specifically, the present invention relates to a process for applying a thin metal foil onto a semiconductor wafer. As explained in the background section, the conventional wisdom in the packaging industry is to use vaporization or sputtering to apply a metal layer directly onto a semiconductor wafer. This approach, while useful in many applications, can have disadvantages. For one, vaporization and sputtering techniques can require the use of expensive equipment. The processes themselves can also be relatively time-consuming. Additionally, existing sputtering equipment is generally not well suited for use with extremely thin wafers (e.g., wafers with a thickness of less than 5 mils.) When extremely thin wafers are not properly supported by the sputtering equipment, they tend to lose their flatness, which may cause the metal layer to accumulate unevenly on the surface of the wafer during the sputtering process or damage the wafer during processing.

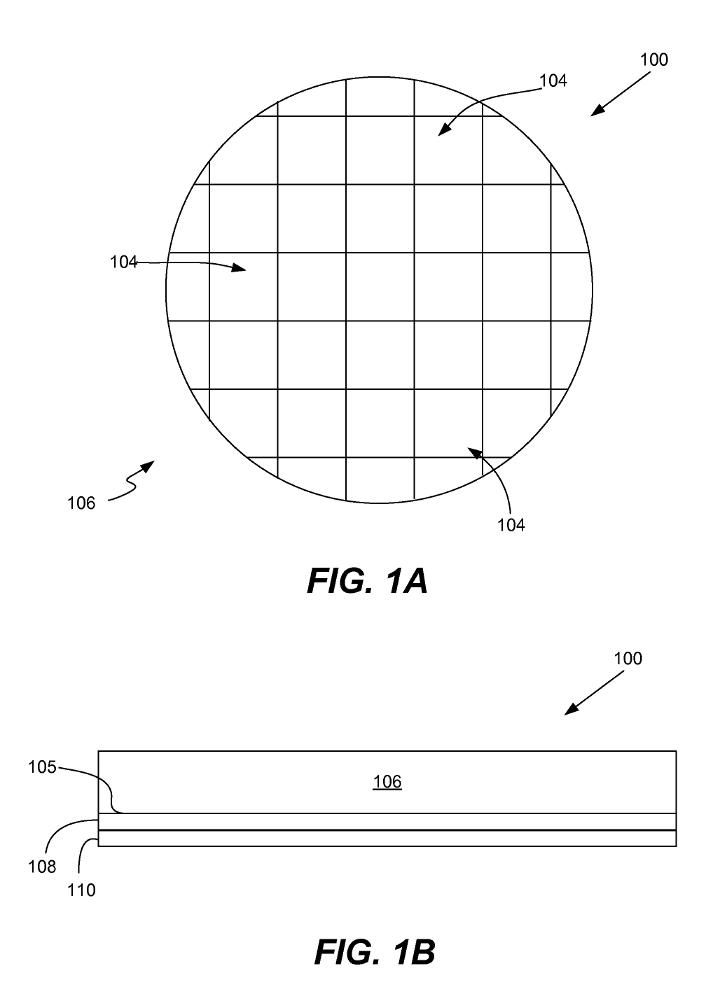

Various embodiments of the present invention address one or more of the above concerns. One embodiment of the present invention is illustrated in FIGS. 1A and 1B. FIGS. 1A and 1B illustrate top and side views of an arrangement 100 that can be used to form exposed die packages. The arrangement includes a semiconductor wafer 106 that is attached with a thin metal foil 110. The metal on the back surface 105 of the semiconductor wafer 106 has not been applied using sputtering or vaporization. Instead, it is adhered to the wafer 106 using an adhesive layer 108.

The above implementation can have several advantages. For one, attaching a foil to a wafer in the described manner may be faster and more affordable than a corresponding sputtering process. A wide variety of techniques may be used to bond the foil 110, wafer 106 and adhesive layer 108 together. By way of example, lamination works well for various applications. Some of these bonding operations, such as lamination, are also compatible with the use of extremely thin wafers (e.g., wafers with a thickness of less than 5 or 6 mils.) The use of a thinner wafer can reduce the size and footprint of integrated circuit packages that are formed from the wafer.

It should be appreciated that the described implementation is believed to be a significant advance over existing backmetal processes. To the best knowledge of the inventors, existing backmetal processes do not involve attaching a metal foil 110 to a semiconductor wafer 106 with an adhesive layer 108 in the manner illustrated in FIGS. 1A and 1B. There may be various reasons as to why the packaging industry has apparently focused instead on the use of sputtering and vaporization to deposit metal directly onto a semiconductor wafer. For one, sputtering and vaporization work well for many applications, and the industry may not have fully appreciated the benefits of the approach described herein. Additionally, there may have been a perception that the adhesive layer that bonds the foil to the wafer might limit heat dissipation and act as an insulant between the die and its external environment. As will be described in greater detail below, various embodiments of the present invention address this issue by using a thermally (and possibly electrically) conductive adhesive layer.

Returning now to FIG. 1A, the semiconductor wafer 106 includes multiple integrated circuit dice 104. Each die 104 includes an active surface and an opposing back surface. The back surfaces of the dice 104 cooperate to form the back surface 105 of the semiconductor wafer 106. Although only a few dice 104 are shown in the wafer 106, a single wafer 106 will typically contain hundreds or thousands of dice. As is well known in the art, most wafers or dice are formed from silicon, although any other appropriate semiconductor material can also be used, including, by way of example, gallium arsenide (GaAs), indium gallium phosphide, silicon germanium, and the like. The thickness of the semiconductor wafer 106 may vary widely, depending on the needs of a particular application. As discussed earlier, at least some of the methods described herein can support a semiconductor wafer 106 with a thickness of less than 5 or 6 mils. During later stages of the packaging process, the dice 104 will be singulated along projected saw streets 102.

The thermally conductive adhesive layer 108 is arranged to form a strong bond between the metal foil 110 and the semiconductor wafer 106. The bond formed by the adhesive layer 108 is arranged to tolerate temperature extremes and other stresses produced by various stages of the packaging process. In various embodiments, the adhesive layer 108 has a thermal conductivity that is approximately equal to or greater than a thermal conductivity of solder. For example, some implementations involve an adhesive layer 108 that has a thermal conductivity in excess of approximately 25, 50 or 60 W/(m·K). The adhesive layer 108 can be made from a wide variety of suitable materials, including epoxy. In some embodiments, the adhesive layer 108 is also electrically conductive and may be filled with metal particles. By way of example, a B staged nanosilver paste or an epoxy filled with silver particles work well for various applications, although other suitable adhesives may also be used.

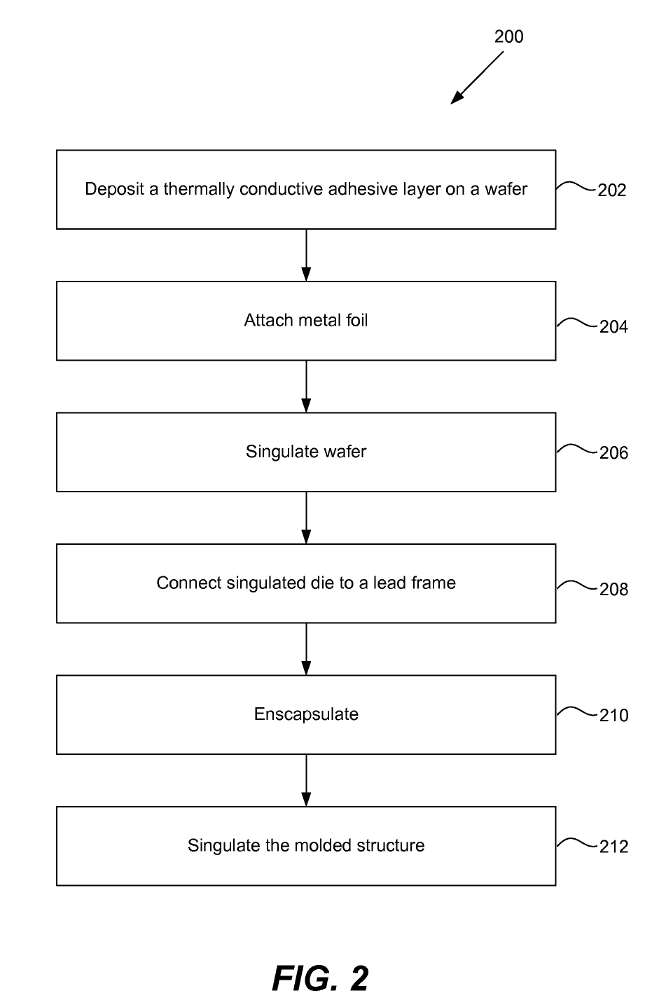

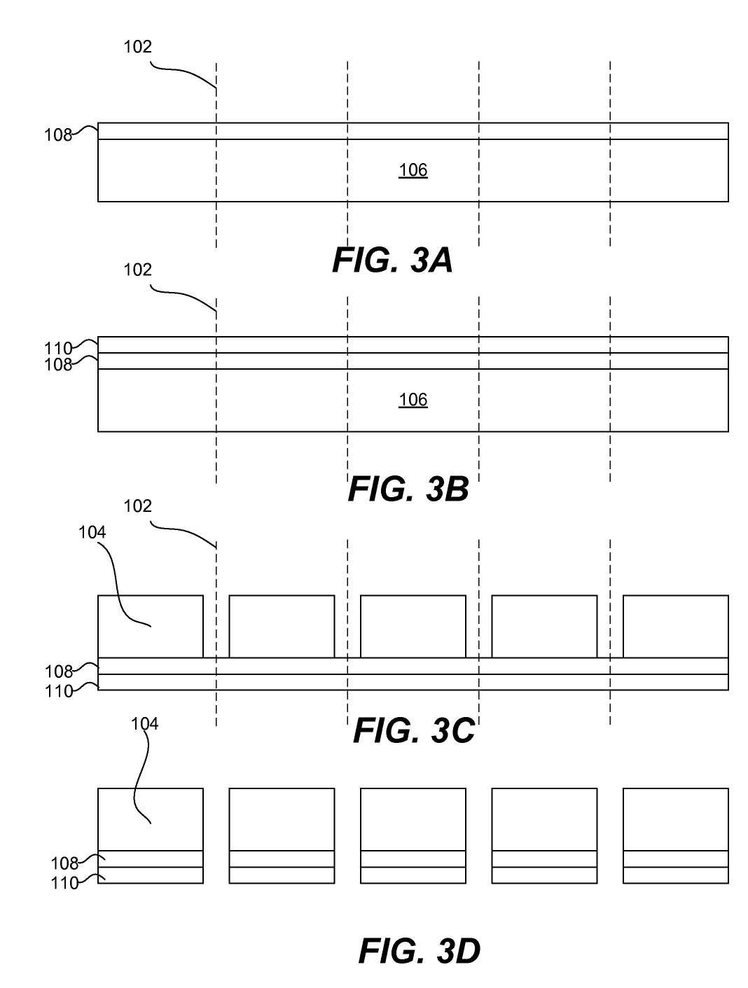

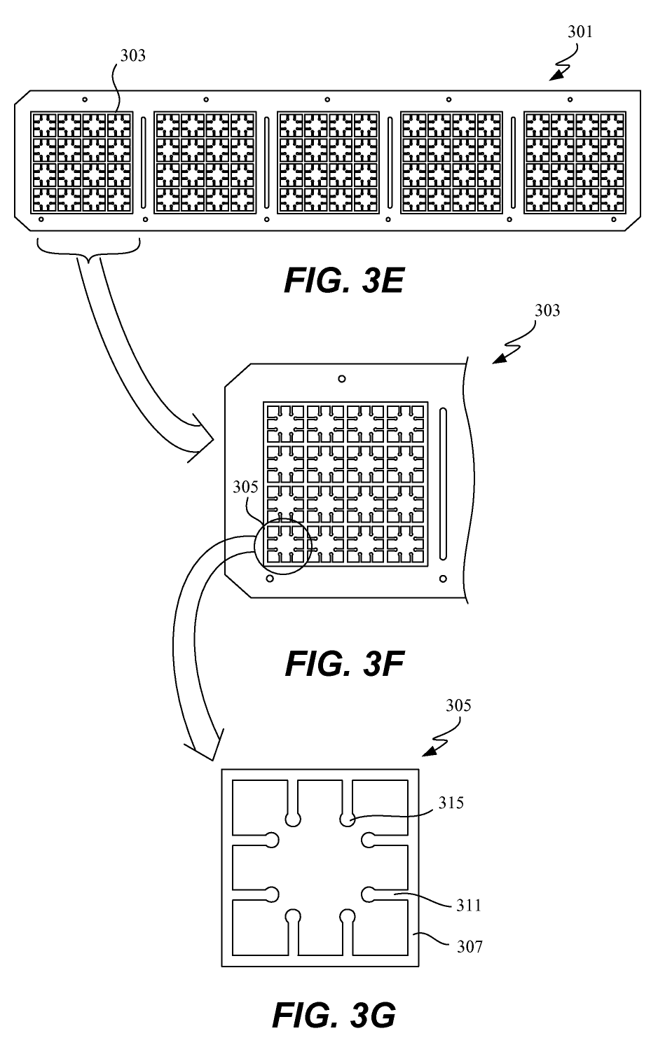

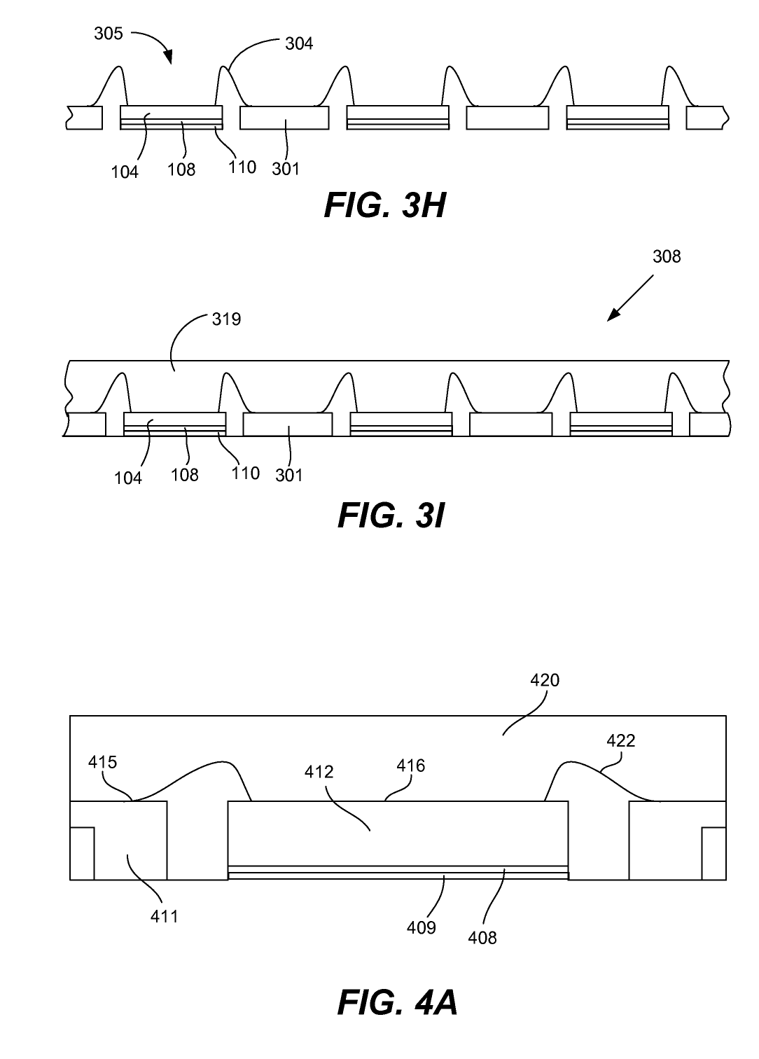

Referring next to FIG. 2 and FIGS. 3A-I, a method 200 for forming an integrated circuit package according to a particular embodiment of the present invention will be described. Initially, in step 202, a thermally conducive adhesive layer 108 of FIG. 3A is deposited onto a back surface of a semiconductor wafer 106. In various embodiments, the adhesive layer is evenly applied across the entire back surface of the wafer 106. In step 204 and FIG. 3B, a metal foil 110 is attached onto the back surface of the wafer 106. That is, the adhesive layer 108 is sandwiched between the metal foil 110 and the wafer 106 and helps to bond the wafer 106 and the foil 110 together.

The foil 110 may be made of any suitable, thermally conductive material. By way of example, copper works well as a material for the foil 110. The metal foil can be a foil, mesh, or metal cloth with high weaves. The thickness of the foil 110 may vary considerably. In some embodiments, the foil 110 has a thickness that is less than approximately 35 microns. In still other embodiments, the foil has a thickness between approximately 15 to 35 microns, although thicker and thinner foils may also be used in various applications. In some implementations, the thickness of the foil 110 is uniform across the entire back surface of the semiconductor wafer.

Various processes may be used to bond the foil 110, adhesive layer 108 and wafer 106 together. For example, in some embodiments the various layers are laminated together. In still other embodiments, the adhesive layer 108 is cured after the foil 110 has been applied over the semiconductor wafer. Various approaches involve attaching the foil 110, adhesive layer 108 and wafer 106 with one another to form the bonded arrangement 100 illustrated in FIGS. 1A and 1B.

Afterward, the bonded arrangement is singulated along projected saw streets 102, as indicated in step 206 and FIGS. 3C-3D. The singulation process forms multiple integrated circuit dice 104. The back surface of each die is covered with a corresponding adhesive layer 108 and a metal foil 110. Any suitable singulation process known in the art may be used, such as sawing or laser cutting.

Some implementations involve at least two distinct cutting operations. By cutting through the semiconductor wafer and the foil in separate stages, the smoothness of the cuts may be improved and/or wear and tear on the sawing blades may be reduced. For example, some approaches involve a first set of one or more cutting operations and a second set of one or more cutting operations. In the first set of cutting operations, the cuts penetrate (entirely) through the semiconductor wafer 106 without cutting the foil 110. An example of such cutting operations is illustrated in FIG. 3C. In some embodiments, the first set of cutting operations involves cutting through at least some of the adhesive layer 108 and/or revealing portions of the underlying foil 110. In the second set of cutting operations, the cuts penetrate (entirely) through the foil 110 without cutting the semiconductor wafer 106 (e.g., FIG. 3D.) The order of the first and second sets of cutting operations may also be reversed or otherwise modified. It should be noted that the present invention also contemplates methods where the both the foil and the wafer are cut through in a single set of cutting or sawing operations.

Afterward, the singulated dice 104 are attached to and electrically connected with a lead frame 301, which may be formed from any suitable electrically conductive material (step 208 and FIG. 3H). The lead frame 301 serves as an electrical interconnect for the resulting integrated circuit package. In a preferred embodiment, the lead frame 301 is in the form of strip. FIG. 3E illustrates a diagrammatic top view of a lead frame panel 301 arranged in the form of a strip. The lead frame panel 301 can be configured as a metal structure with a number of two-dimensional arrays 303 of device areas. As illustrated in the successively more detailed FIGS. 3E-F, each two-dimensional array 303 includes a plurality of device areas 305, each configured for use in a single IC package, and each connected by fine tie bars 307.

Each device area 305 may include a number of leads 311, each supported at one end by the tie bars 307. In the illustrated embodiment, the leads 311 include conductive die contacts 315 on the top surface of the lead frame at the proximal end of the lead. The leads 311 additionally include package contacts on the bottom surface of the lead frame at the distal ends of the leads. The leads 311 may be etched, half-etched, or otherwise thinned relative to the package contacts, so as to provide electrical connection to the contacts without leaving exposed conductive areas on the bottom surface of the lead frame panel 301. Additionally, it may also be desirable to etch or otherwise thin the top surface of the lead frame as well.

It will be appreciated by those skilled in the art that, although a specific lead-frame panel 301 has been described and illustrated, the described methods may be applied in packaging dice utilizing an extremely wide variety of other lead frame panel or strip configurations as well as other substrates. Thus, although the following description of particular embodiments describes the packaging of dice utilizing lead frame technology, those of skill in the art will understand that embodiments of the present invention may also be practiced using other substrates. Additionally, although described with references to a top and bottom surface of the lead frame panel 301, it should be appreciated that this context is intended solely for use in describing the structure and in no way defines or limits the orientation of the lead frame for subsequent attachment to a PCB or other substrate.

The dice 104 may be electrically connected to the lead frame 301 in any suitable manner, depending on the needs of a particular application art e.g., flip chip configuration, wirebonding, etc. By way of example, dice 104 of FIG. 3H may be positioned onto or within a lead frame 301 at step 208. Each die 104 is positioned within a die attach area of a lead frame device area 305 that does not include a die attach pad. In the illustrated embodiment of FIG. 3H, for example, the dice 104 are positioned such that the metal foil 110 on the bottom surface of each die 104 is substantially coplanar with the bottom surface of the lead frame 301, although of course other lead frame arrangements are also possible. Bond pads on the active surface of the dice are electrically connected to contacts 315 located on the leads 311 of the lead frame with bonding wires 304.

The dice 104 may be electrically coupled to the lead frame 301 in ways that differ from what is illustrated in FIG. 3H. For example, the active face of the dice may be directly attached with the lead frame 301 using solder bumps. When placing solder-bumped dice onto the lead frame 301, the solder bumps may be directly positioned onto contacts 315 located on the leads 311 of the lead frame. In embodiments such as these in which the active surface of each die includes a plurality of solder bumps, the die is electrically and physically connected to the lead frame 301 by means of reflowing the solder bumps at step 208 such that solder joints are formed between the bonds pads on the active surface of the die and the contacts 315 of the lead frame.

At step 210 and FIG. 3I, portions of the dice and lead frame are encapsulated in a molding compound 319. The molding compound 319 is generally a non-conductive plastic or resin having a low coefficient of thermal expansion. In a preferred embodiment, an entire populated lead frame strip, such as lead frame panel 301, is placed in the mold such that the entire die-populated lead frame panel may be encapsulated substantially simultaneously. It should be appreciated that a lesser number of dice may also be encapsulated at any one time.

It should additionally be appreciated that virtually any molding system may be used to encapsulate the attached dice 104 and lead frame panel 301. By way of example, a film assisted molding (FAM) system may be used to encapsulate the attached dice 104. In such a system, a vacuum is used to draw a film or tape to the inner surfaces of the molding cavity. By way of example, the film used within the mold cavity may be a thermoplastic adhesive film. In this way, portions of the lead frame panel and dice 104 that would make contact with the mold cavity during encapsulation instead make contact with the adhesive film. Thus, in one embodiment, during encapsulation, the surface of the metal foil 110 opposite the back surface of each die 104 is in contact with the adhesive film, which is turn in contact with the mold cavity. The adhesive film generally aids in reducing mold compound intrusion over the back surfaces of the dice 104.

However, FAM systems are not always available or applicable to particular lead frame configurations. Hence, one approach involves initially positioning the populated lead frame 301 in a molding cavity. The lead frame 301 and dice 104 are positioned within the mold cavity such that the metal foil 110 on the bottom surface of each die is pressed flush against the mold cavity. Afterward, the molding compound 319 is injected into the mold cavity. The pressing together of the dice 104 and the mold cavity helps prevent molding compound 319 from covering the metal foil 110. In various embodiments, the mold cavity may or may not be covered with an adhesive film. In the former case, the metal foil 110 on the bottom surface of each die 104 is instead pressed flush against the film overlying the mold cavity, rather than against the mold cavity itself.

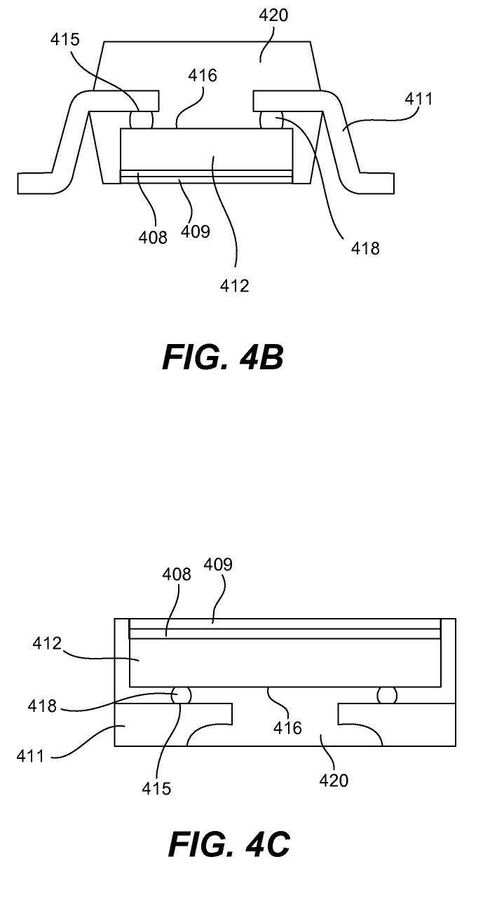

After the encapsulation process (step 210), the encapsulated lead frame panel 308 may then be singulated (step 212) to yield a plurality of individual IC packages having exposed metal foils on the back surfaces of the packaged dice. Examples of such packages include those illustrated in FIGS. 4A-4C. The encapsulated lead frame panel 301 may be singulated with any suitable means. By way of example, the lead frame panel 301 may be sawed to produce individual IC packages. Upon package singulation, the exposed IC packages may be attached to PCBs or other desired substrates. In many applications, the exposed metal foils of the IC packages may be soldered directly to PCBs. It should be appreciated that the more surface area of the metal foil that is exposed the stronger the resultant solder bond is between the package and the PCB, and the more heat transfer that is possible out of the die. Alternatively, in other embodiments it may be desirable to solder a heat sink onto the exposed metal layer. Again, it is desirable to maximize the exposed surface area of the metal foil in these embodiments as well.

Various examples of individual integrated circuit packages are illustrated in FIGS. 4A-4C. In the embodiment illustrated in FIG. 4A, a die 412 not having solder bumps is positioned within a die attach area of a lead frame that does not include a die attach pad. In this embodiment, bond pads on the active surface 416 of the die are electrically connected to contact surfaces 415 on the leads 411 via bonding wires 422. Again, the die 412 and portions of the leads 411 are encapsulated with molding compound 420 while leaving metal foil 409 on the back surface of the die exposed. The metal foil 409 is secured to the back surface of the die 412 with the thermally (and possibly electrically) conductive adhesive layer 408.

FIGS. 4B-4C illustrate various exposed flip-chip-on-lead (FCOL) package configurations employing solder-bumped dice 412 in accordance with particular embodiments of the present invention. The packages illustrated in FIGS. 4B and 4C include a die 412 having an exposed metal foil 409 on the back surface of the die. The metal foil 409, which was previously part of the larger metal foil 110 of FIG. 1B, is bonded to the back surface of the die with an intervening thermally conductive adhesive layer 408. The die 412 and portions of the leads 411 are encapsulated with molding compound 420 except for the exposed metal foil 409. The die 412 is electrically and mechanically connected to the leads 411 via solder joints 418 that electrically and mechanically connect bond pads on the active surface 416 of the die to contact surfaces 415 on associated leads. FIG. 4B illustrates an exposed FCOL package in which the leads 411 are bent into a gull-wing formation to facilitate electrical connection to a PCB. In the configuration illustrated in FIG. 4B, the metal foil 409 on the back surface of the die 412 may be directly soldered to a contact surface on a PCB. While FIG. 4C also illustrates an FCOL package, the metal foil 409 in FIG. 4C is generally not intended to be soldered to a PCB.

Although only a few embodiments of the invention have been described in detail, it should be appreciated that the invention may be implemented in many other forms without departing from the spirit or scope of the invention. In the foregoing description, the figures may be understood as showing additional features that are not specifically pointed out in the written specification. For example, based on a review of FIGS. 1A and 1B, it can be assumed that various implementations of the present invention involve a wafer, adhesive layer and foil that each have a substantially uniform thickness. In some embodiments, the wafer, adhesive layer and foil are stacked over one another and have substantially equal surface areas. In still other embodiments, the foil is in direct contact with one side of the adhesive layer and the wafer is in direct contact with the opposing side of the adhesive layer. Various implementations involve a metal foil that is in the form of a preformed sheet prior to its attachment to the wafer. That is, the metal foil is not gradually formed on the adhesive layer and/or the wafer using processes such as sputtering, vaporization or electroplating. The above features, however, are not required and the arrangement illustrated in FIGS. 1A and 1B may be modified to address the needs of particular applications. Therefore, the present embodiments should be considered as illustrative and not restrictive and the invention is not limited to the details given herein, but may be modified within the scope and equivalents of the appended claims.

What is claimed is:

1. An arrangement comprising:
a semiconductor wafer that includes a multiplicity of integrated circuit dice formed therein, each die having an active surface and a back surface, each back surface being substantially opposite the active surface, the back surfaces of the dice cooperating to form the back surface of the wafer;
a thermally conductive adhesive layer that covers the back surface of the semiconductor wafer; and
a metal foil that is adhered to the semiconductor wafer with the adhesive layer.

2. An arrangement as recited in claim 1, wherein the adhesive layer has a thermal conductivity than is approximately equal to or greater than a thermal conductivity of solder.

3. An arrangement as recited in claim 1, wherein the adhesive layer is electrically conductive and includes metal particles.

4. An arrangement as recited in claim 1, wherein the metal foil is made of copper and the adhesive layer includes at least one selected from a group consisting of an epoxy filled with silver particles and a B staged nanosilver paste.

5. An arrangement as recited in claim 1, wherein the metal foil is one selected from a group consisting of a foil, a mesh and a cloth with high weaves.

6. An arrangement as recited in claim 1, wherein the metal foil, the adhesive layer and the wafer are laminated together.

7. An arrangement as recited in claim 1, wherein the thickness of the wafer is less than approximately 6 mils.

8. An arrangement as recited in claim 1, wherein the metal foil has a thickness that is less than approximately 35 microns.

9. A method of packaging integrated circuit dice into exposed die packages, the method comprising:
depositing a thermally conductive adhesive layer onto a back surface of an integrated circuit wafer, the wafer including a multiplicity of integrated circuit dice formed therein, each die having an active surface and a back surface, each back surface being substantially opposite the active surface, the back surfaces of the dice cooperating to form the back surface of the wafer, the adhesive layer being deposited such that the adhesive layer substantially covers the back surface of the wafer; and
attaching a metal foil onto the back surface of the wafer with the adhesive layer.

10. A method as recited in claim 9, further comprising laminating the wafer, the adhesive layer and the metal foil together.

11. A method as recited in claim 9, further comprising:
singulating the wafer into the multiplicity of individual integrated circuit dice;
electrically connecting one of the singulated dice to a lead frame having a plurality of contacts; and
encapsulating at least portions of the one of the dice and the lead frame with a molding compound to form an encapsulated structure, wherein the metal foil on the back surface of the one of the dice is exposed on the exterior of the encapsulated structure.

12. A method as recited in claim 11, wherein the singulating of the wafer involves a first sawing operation and a distinct second sawing operation, wherein the first sawing operation involves cutting through the wafer and the second sawing operation involves cutting through the metal foil without substantially cutting through the wafer.

13. A method as recited in claim 9, wherein the adhesive layer is applied using at least one of a group selected from spray- and spin-coating.

14. A method as recited in claim 11, wherein the lead frame is in the form of a strip and includes at least one two-dimensional array of device areas, adjacent device areas being connected with associated tie bars, each device area being suitable to receive an associated die, wherein the method comprises electrically connecting a plurality of the dice to the lead frame strip, each die being electrically connected to an associated device area, and wherein the entire lead frame strip is encapsulated with the molding compound substantially simultaneously, the method further comprising singulating the encapsulated dice and lead frame after curing the molding compound to provide individual IC packages each having a die with an exposed metal foil on a back surface thereof.

15. A method as recited in claim 11, further comprising:
prior to the encapsulating of the one of the dice and the lead frame, positioning the lead frame inside a mold cavity such that the metal foil on the back surface of the one of the dice is pressed flush against the mold cavity.

16. A method as recited in claim 9, further comprising curing the adhesive layer.

17. A method as recited in claim 9, wherein the thickness of the wafer is less than approximately 6 mils.

18. A method as recited in claim 9, wherein the adhesive layer has a thermal conductivity than is approximately equal to or greater than a thermal conductivity of solder.

19. A method as recited in claim 9, wherein the adhesive layer is electrically conductive and includes metal particles.

20. A method as recited in claim 9, wherein the metal foil is preformed as a sheet prior to its attachment to the wafer.
